(19) United States
(12) Patent Application Publication
(10) Pub. No.: US 2014/0167173 A1
(43) Pub. Date: Jun. 19, 2014

(54) INCREASING THE BREAKDOWN VOLTAGE OF A METAL OXIDE SEMICONDUCTOR DEVICE

(71) Applicant: BROADCOM CORPORATION, Irvine, CA (US)

(72) Inventor: Akira Ito, Irvine, CA (US)

(73) Assignee: BROADCOM CORPORATION, Irvine, CA (US)

(21) Appl. No.: 13/715,740

(22) Filed: Dec. 14, 2012

(51) Int. Cl. H01L 29/78; H01L 29/66

(52) U.S. Cl. CPC H01L 29/78; H01L 29/66477
USPC 257/368; 257/409; 438/294

(57) ABSTRACT

A semiconductor device includes a first well, a second well, and a separator structure. The first well and the second well are implanted in the semiconductor substrate. The separator structure is also implanted in the semiconductor substrate and separates the first well and the second well so that the first well and the second well do not contact each other.

### TECHNICAL FIELD

This disclosure relates generally to a metal oxide semiconductor field effect transistor (MOSFET). More particularly, it relates to fabrication methods and device structures that increase the breakdown voltage of a laterally diffused metal oxide semiconductor (LDMOS).

### BACKGROUND

Silicon semiconductor processing has evolved sophisticated operations for fabricating integrated circuits. As advancement in fabrication process technology continues, the core and Input/Output (I/O) operating voltages of integrated circuits have decreased. However, operating voltages of auxiliary devices have remained about the same. The auxiliary devices include devices interfaced to the integrated circuits. For example, the auxiliary devices may be printers, scanners, disk drives, tape drives, microphones, speakers, or cameras.

An integrated circuit may include an interconnected array of active and passive elements, such as transistors, resistors, capacitors, and inductors, integrated with or deposited on a substrate by a series of compatible processes. The auxiliary devices may operate at voltages above a breakdown voltage of the transistors contained within the integrated circuit. As the operating voltages applied to the transistors increase, the transistors will eventually breakdown allowing an uncontrollable increase in current. Examples of the detrimental effects of breakdown may include punch-through, avalanche breakdown, and gate oxide breakdown to provide some examples. Furthermore, operating above the breakdown voltage for a significant duration reduces the lifetime of the transistors.

### BRIEF DESCRIPTION OF THE DRAWINGS

The disclosed method and apparatus may be better understood with reference to the following drawings and description. In the figures, like reference numerals designate corresponding parts throughout the different views.

FIG. 1 shows a cross-sectional view of a semiconductor device according to a first exemplary embodiment.

FIG. 2 shows a cross-sectional view of a semiconductor device according to a second exemplary embodiment.

FIG. 3 shows a cross-sectional view of a semiconductor device according to a third exemplary embodiment.

FIG. 4 shows a cross-sectional view of a semiconductor structure according to a fourth exemplary embodiment.

FIG. 5 shows a cross-sectional view of a semiconductor structure according to a fifth exemplary embodiment.

FIG. 6 shows a cross-sectional view of a semiconductor structure according to a sixth exemplary embodiment.

FIG. 7 shows a cross-sectional view of a semiconductor structure according to a seventh exemplary embodiment.

FIG. 8 shows a cross-sectional view of a semiconductor structure according to an eighth exemplary embodiment.

FIG. 9 shows an exemplary method to manufacture a semiconductor device.

### DETAILED DESCRIPTION

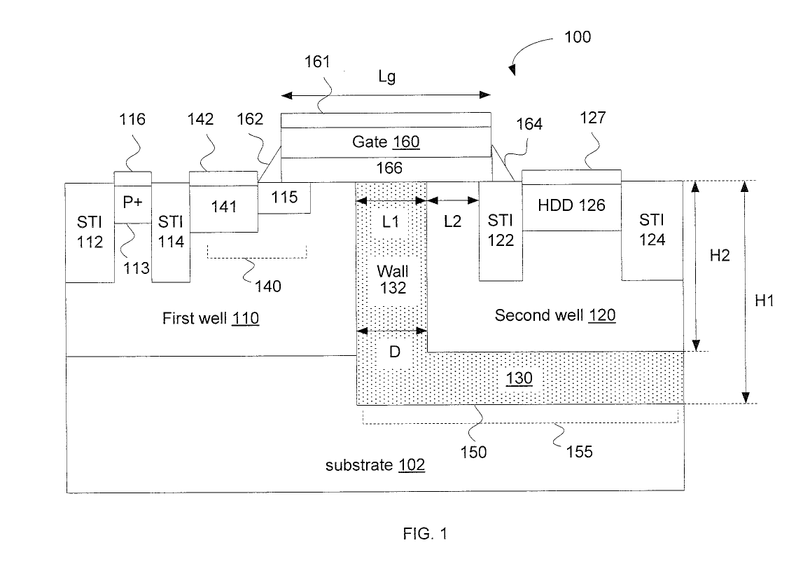

FIG. 1 shows a cross-sectional view of a semiconductor device 100 according to a first exemplary embodiment. For example, the semiconductor device 100 may be an n-type metal oxide semiconductor (NMOS) structure. The semiconductor device 100 includes a first well 110, a second well 120, and a separator structure 150. The first well 110 is implanted in a semiconductor substrate 102. The second well 120 is also implanted in the semiconductor substrate 102. The separator structure 150 is also implanted in the semiconductor substrate 102 and separates the first well 110 and the second well 120 so that the first well 110 and the second well 120 do not contact each other.

In an embodiment, the semiconductor substrate 102 is a p-type substrate made of p-type material. The p-type material may be obtained by a doping process by adding a certain type of atoms to the semiconductor in order to increase the number of positive carriers (holes). Alternatively, the semiconductor substrate 102 may be an n-type substrate. The first well 110 may be formed by implanting a first material having a first conductivity type. The second well 120 may be formed by implanting a second material having a second conductivity type into the substrate 102. The first material may be a p-type material such as boron or other suitable materials. The second material may be an n-type material such as phosphorous, arsenic, or other suitable materials.

The first well 110 includes a source region 140. In an embodiment, the source region 140 of an NMOS structure may include an N+ region 141 and an N-LDD region 115. LDD refers to lightly doped drain (LDD) that has a lighter carrier concentration than a highly doped drain (HDD) that may be designated by a “+.” An LDD region may be designated by a “−” following a letter “N” or “P”, which indicate a n-type material or a p-type material. Thus, the N-LDD region 115 has a lighter concentration of n-type material than N+ region 141. The N-LDD region may have a concentration of n-type material in the ranges of approximately 1×10¹⁷ to 5×10¹⁷ n-type atoms per cubic centimeter. Concentrations may be abbreviated as simply “cm⁻³” in this document. The first well 110 may have a concentration of p-type material in the ranges of 5×10¹⁶cm⁻³ to 1×10¹⁸cm⁻³, which similarly means that there are about 5×10¹⁶ to 1×10¹⁸ p-type material atoms per cubic centimeter.

The first well 110 further includes a first shallow trench isolation (STI) region 112 and a second STI region 114. In an embodiment, there is also a P+ region 113 between the first STI region 112 and the second STI region 114. The STI regions 112 and 114 may include a dielectric material, such as SiO₂ or other suitable material. The STI regions 112 and 114 can provide isolation and protection for the NMOS structure.

The second well 120 includes a highly doped drain (HDD) region 126 between a third STI region 122 and a fourth STI region 124. In an NMOS structure, the HDD region 126 may be an N-HDD region. There is a distance L2 between the side wall 132 and the STI region 122. In an embodiment, L2 is greater than or equal to 0.2 μm. The second well 120 has a depth H2. A drain region 155 in the semiconductor device 100 may include the second well 120 and the HDD region 126. The N-HDD region 126 may have a concentration of n-type material in the ranges of 1×10¹⁹cm⁻³ to 1×10²¹cm⁻³. The second well 120 may have a concentration of n-type material in the ranges of 5×10¹⁶ cm⁻³ to 1×10¹⁸ cm⁻³.

The semiconductor device 100 further includes a gate region 160 disposed between and running over the source region 140 and the drain region 155. The gate region 160 is located between two spacers 162 and 164. The spacers are typically a dielectric material, such as SiO₂, though any suitable material can be used. In an embodiment, the gate region 160 is on top of a gate oxide region 166. The gate region 160 has a length Lg. In an embodiment, the gate length Lg is greater than or equal to 0.6 μm.

In FIG. 1, the length Lg is greater than the wall thickness L1 and the distance L2. The wall thickness L1 in this example is the same as the distance between the first well 110 and the second well 120. A distance D between the first well 110 and the second well 120 is equal to the wall thickness L1 of the separator well 130.

In FIG. 1, the separator structure 150 also includes a separator well 130. The separator well 130 and the second well 120 are implanted with a same material having the second conductivity type. For example, the separator well 130 is implanted with a lower concentration of n-type material than the second well 120. The separator well 130 may have a concentration of n-type material in the ranges of 5×10¹⁵ cm⁻³ to 1×10¹⁸ cm⁻³. In an embodiment, the drain region 155 may include at least part of the separator well 130.

The separator well 130 may be a deep N-well that includes the side wall 132. In an embodiment, the side wall 132 is configured to separate the first well 110 and the second well 120 so that they do not contact each other. The side wall 132 may completely separate the first well 110 and the second well 120. The separator structure 150, including the side wall 132 and the well 130, may completely surround the second well 120 so that the second well 120 is isolated from the first well 110 and the substrate 102. The side wall 132 may have different shapes and a wide range of thickness L1. The side wall 132 may have a uniform or non-uniform thickness along the depth direction. In an embodiment, the wall thickness L1 is greater than or equal to 0.2 μm. The separator well 130 has a depth H1 that is greater than the depth H2 of the second well 120.

The semiconductor device 100 may include silicide layers 116, 142, 161, and 127. The silicide layer 116 is on top of a P+ region 113 between the STI regions 112 and 114. The silicide layer 142 is on top of the N+ region 141. The silicide layer 127 is on top of the HDD region 126 between the STI regions 122 and 124. The silicide layer 161 is on top of the gate region 160.

One of the uses of silicide, an alloy of metal and silicon, is to form a low resistance interconnection between other devices within an integrated circuit. The P+ region 113 may have a concentration of p-type material in the ranges of 1×10¹⁹ cm⁻³ to 1×10²¹ cm⁻³. The N+ region 141 may have a concentration of n-type material in the ranges of 1×10¹⁹ cm⁻³ to 1×10²¹ cm⁻³.

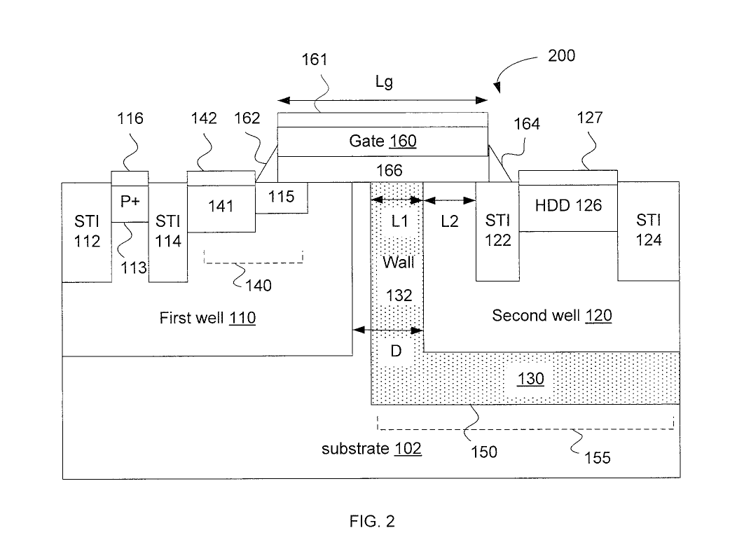

FIG. 2 shows a cross-sectional view of a semiconductor device 200 according to a second exemplary embodiment. One of the differences between the second exemplary embodiment and the first exemplary embodiment is that a distance D between the first well 110 and the second well 120 is greater than the wall thickness L1 of the separator well 130. The distance D is less than the gate length Lg. The sum of the distance D and the distance L2 may be less than the length Lg of the gate region 160. Both the wall thickness L1 and the distance D may be greater than or equal to 0.2 μm. The distance between the first well 110 and the STI region 122 may be greater than or equal to 0.4 μm.

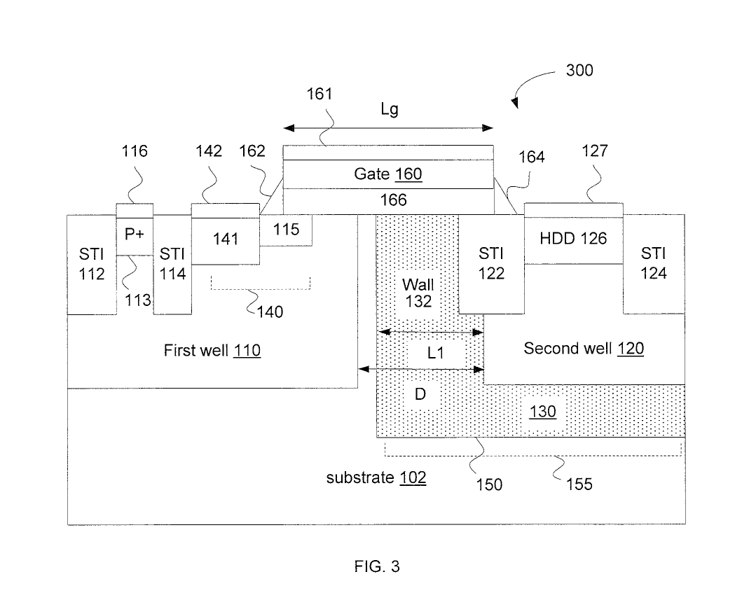

FIG. 3 shows a cross-sectional view of a semiconductor device 300 according to a third exemplary embodiment. One of the differences between the third exemplary embodiment 300 and the second exemplary embodiment 200 is that the STI region 122 is partially in the second well 120 and partially in the side wall 132 of the separator well 130. The distance D between the first well 110 and the second well 120 is greater than the wall thickness L1.

In FIGS. 1-3, the structures include p-n junctions that have a potential barrier created by adjacent n-type and p-type material. Without a bias voltage on the gate region 160, two p-n junctions exist in series between the source 140 and the drain 155. One such junction is between the drain 155 and the substrate 102, and the other junction is between the substrate 102 and source 140. These p-n junctions prevent current conduction from the source 140 to the drain 155 upon the application of a source to drain voltage.

Upon grounding the source 140 and applying a positive voltage to the gate 160, a voltage appears between the gate 160 and the source 140. The positive voltage on the gate 160 repels the positively charged carrier holes from underneath the gate oxide 166. The pushing away of the carrier holes from the gate oxide 166 interface into substrate 102 forms a depletion region, or channel. The formed channel is a carrier-depletion region populated by the negative charge formed below the interface at the gate oxide 166 and substrate 102 by the electric field created between the gate 160 and the substrate 102. In addition to repelling the carrier holes, the positive gate voltage attracts carrier electrons from the source 140 and the drain 155 into the formed channel. When a sufficient number of carrier electrons accumulate in the formed channel, an n-type region is created connecting the source 140 to the drain 155. Thus, applying a voltage between the source 140 and the drain 155 may cause current to flow through channel 122.

As the operating voltage applied to drain of the semiconductor device 100 increases, the drain to gate voltage will eventually cause a breakdown of the gate oxide 166 and the drain to source voltage may cause the breakdown of the device. This breakdown of gate oxide 166 may cause permanent damage to the semiconductor device 100 such as an NMOS structure. With the newly introduced separator structure 150 between the first well 110 and the second well 120 and separate the two wells, the semiconductor devices 100, 200, 300 have a higher drain to source breakdown voltage of more than 15V. The source to gate voltage remains the same compared to the standard LDMOS.

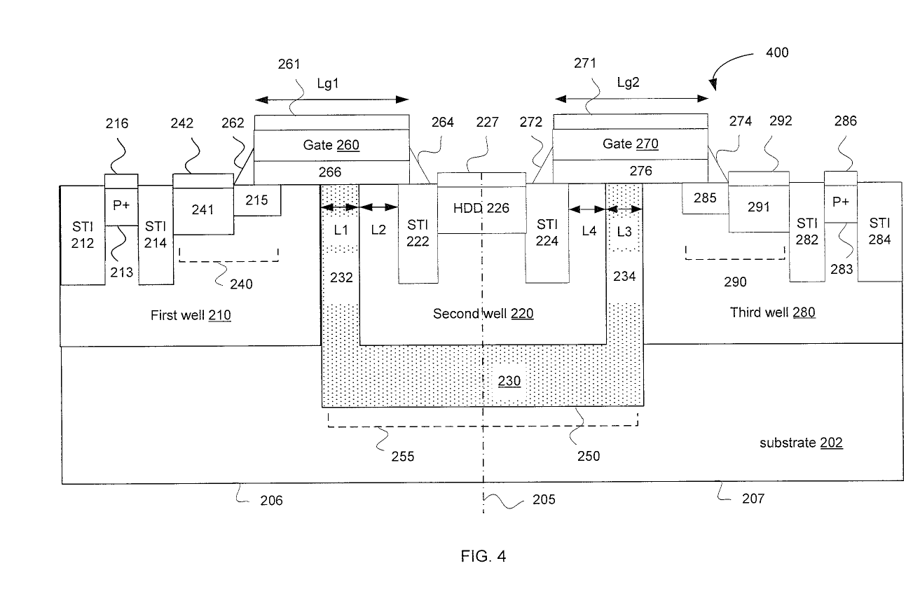

When fabricating the semiconductor devices, it may be more preferable to fabricate many semiconductor devices together in a single process. FIGS. 4-6 show examples of cross-sectional views of how two semiconductor structures may be fabricated side by side with the benefits of higher breakdown voltage.

FIG. 4 shows a cross-sectional view of a semiconductor structure 400 according to a fourth exemplary embodiment. The semiconductor structure 200 includes two NMOS structures 206 and 207 side by side. The NMOS structure 206 has substantially the same structure as the semiconductor device 100 in FIG. 1. The NMOS structure 207 is substantially symmetrical to the NMOS structure 206 along the line 205 in the middle of the semiconductor structure 400.

In FIG. 4, the semiconductor structure 400 includes a first well 210, a second well 220 and a third well 280 implanted on a substrate 202. The substrate may be a p-substrate implanted with a p-type material. The first and second wells 210 and 220 may be implanted with a material having different conductivity type. The first and third wells 210 and 280 may be implanted with a material having the same conductivity type. For example, the first and third wells 210 and 280 may be implanted with a p-type material while the second well 220 may be implanted with an n-type material.

The separator structure 250 includes a separator well 230 having side walls 232 and 234. The side walls 232 and 234 are configured to isolate the second well 220 from the first and third wells 210 and 280. The side walls 232 and 234 respectively have wall thickness L1 and L3. The side wall thickness L1 and L3 may be the same or different. In an embodiment, the side wall thickness L1 and L3 are greater than or equal to 0.2 μm.

The first well 210 includes a source region 240 that include an N+ region 241 and an N-LDD region 215. The first well 210 further includes a first STI region 212 and a second STI region 214. In an embodiment, there is also a P+ region 213 between the first STI region 212 and the second STI region 214.

The second well 220 includes a HDD region 226 between a third STI region 222 and a fourth STI region 224. In an NMOS structure, the HDD region 226 may be an N-HDD region. There is a distance L2 between the side wall 232 and the STI region 222. There is a distance L4 between the side wall 234 and the STI region 224. In an embodiment, L2 and L4 are greater than or equal to 0.2 μm. A drain region 255 may include the second well 220, the HDD region 226, and part of the separator well 230.

The third well 280 includes a source region 290 that include an N+ region 291 and an N-LDD region 285. The third well 280 further includes a fifth STI region 282 and a sixth STI region 284. In an embodiment, there is also a P+ region 283 between the STI regions 282 and 284.

A first gate region 260 is disposed between the source region 240 and the drain region 255. The first gate region 260 is located between two spacers 262 and 264. The spacer 264 is on top of the STI region 222. In an embodiment, the gate region 260 is on top of a gate oxide region 266. The gate region 260 has a length Lg1. In an embodiment, the gate length Lg1 is greater than or equal to 0.6 μm.

A second gate region 270 is disposed between the source region 290 and the drain region 255. The second gate region 260 is located between two spacers 272 and 274. The spacer 272 is on top of the STI region 224. In an embodiment, the second gate region 270 is on top of a gate oxide region 276. The second gate region 270 has a length Lg2. In an embodiment, the gate length Lg2 is greater than or equal to 0.6 μm.

The semiconductor device 400 may include silicide layers 216, 242, 261, 227, 271, 286, and 292. The silicide layer 216 is on top of a P+ region 213 between the STI regions 212 and 214. The silicide layer 242 is on top of the N+ region 241. The silicide layer 227 is on top of the HDD region 226 between the STI regions 222 and 224. The silicide layer 261 is on top of the gate region 260. The silicide layer 271 is on top of the gate region 270. The silicide layer 286 is on top of a P+ region 283 between the STI regions 282 and 284. The silicide layer 292 is on top of the N+region 291.

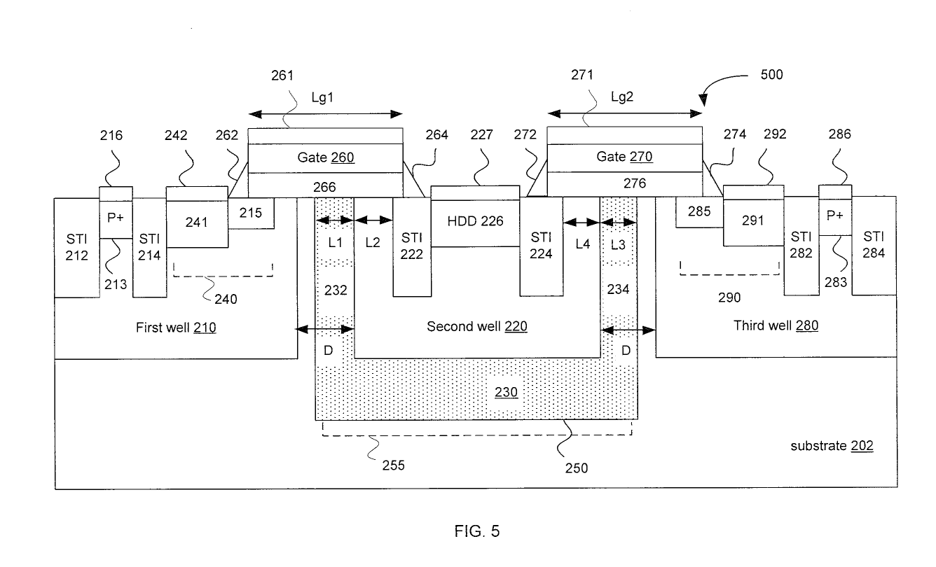

FIG. 5 shows a cross-sectional view of a semiconductor structure 500 according to a fifth exemplary embodiment. One of the differences between the fifth exemplary embodiment 500 and the fourth exemplary embodiment 400 is that a distance D between the first well 210 and the second well 220 is greater than the wall thickness L1 of the separator well 230. Similarly, the distance D between the third well 280 and the second well 220 is greater than the wall thickness L3 of the separator well 230. The gate length Lg1 may be greater than the sum of wall thickness L1 and the distance L2. The gate length Lg2 may be greater than the sum of wall thickness L3 and the distance L4. The gate lengths Lg1 and Lg2 may be substantially the same. The separator walls 232 and 234 have substantially uniform thickness.

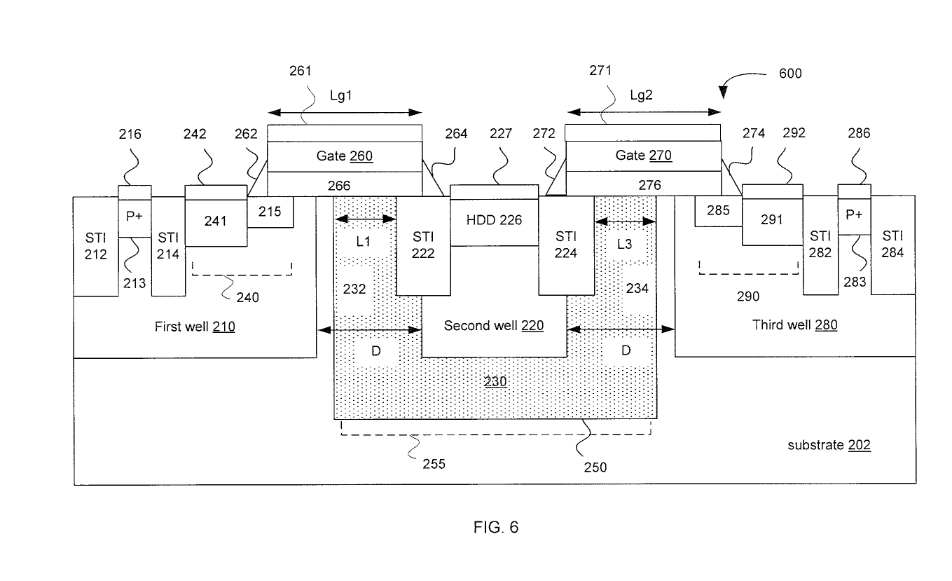

FIG. 6 shows a cross-sectional view of a semiconductor structure 600 according to a sixth exemplary embodiment. In this embodiment, the STI regions 222 and 224 are not completely in the second well 220. The STI regions 222 and 224 are partially in the second well 220 and partially in the separator well 230. The separator walls 232 and 234 have non-uniform thickness. The wall thickness near the gate region 260 and 270 is thinner than the wall thickness near the substrate 202.

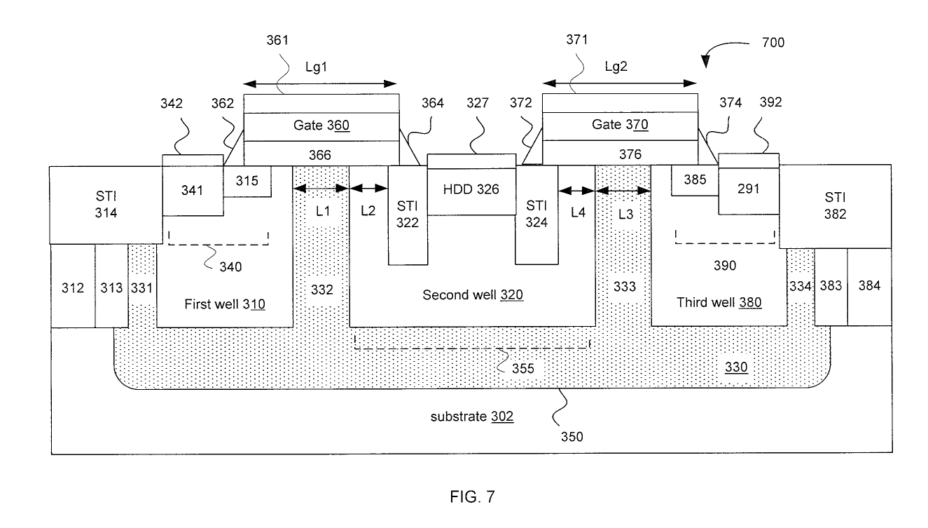

FIG. 7 shows a cross-sectional view of a semiconductor structure 700 according to a seventh exemplary embodiment. In this embodiment, the separator structure 330 further isolates the first well 310 and the third well 380 from the substrate 302. The wells 310, 320, and 380 do not contact the substrate 302 or contact with each other. In an embodiment, the first and third wells 310 and 380 are P wells implanted with a p-type material. The second well 320 and the separator structure 330 are implanted with an n-type material. The separator structure 330 may be a deep N well having a concentration of n-type material in the ranges of 5×10¹⁵ cm⁻³ to 1×10¹⁸ cm⁻³. The separator structure 330 includes separator walls 331, 332, 333, and 334 surrounding the wells 310, 320, and 380.

A STI region 314 is partially in the first well 310 and the separator well 330. The STI region 314 extends out from the separator well 330 and is partially on top of regions 312 and 313. The region 312 may have the same conductive material as in the first well 310. The region 313 may have the same conductive material as in the second well 320.

A STI region 382 is partially in the third well 380 and the separator well 330. The STI region 382 extends out from the separator well 330 and is partially on top of regions 383 and 384. The region 383 may have the same conductive material as in the second well 320. The region 384 may have the same conductive material as in the third well 380.

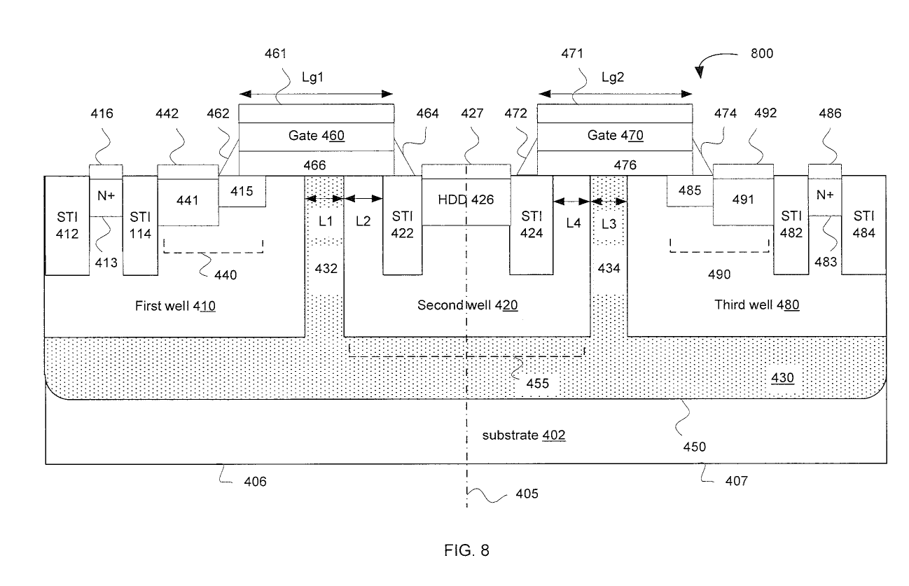

FIG. 8 shows a cross-sectional view of a semiconductor structure 800 according to an eighth exemplary embodiment. The semiconductor structure 800 includes two PMOS structures 406 and 407 side by side and substantially symmetrical along the long 405. In this embodiment, the semiconductor structure 400 includes a first well 410, a second well 420, and a third well 480. The first well 410 and the third well 480 are N wells implanted with an n-type material. The second well 420 is a P well implanted with a p-type material. The wells 410, 420, and 480 are separated from each other by a separator structure 450.

The first well 410 includes a source region 440 that include a P+ region 441 and a P-LDD region 415. The first well 410 further includes a first STI region 412 and a second STI region 414. In an embodiment, there is also an N+ region 413 between the first STI region 412 and the second STI region 414.

The second well 420 includes a HDD region 426 between a third STI region 422 and a fourth STI region 424. For example, the HDD region 426 may be a P-HDD region. There is a distance L2 between the side wall 432 and the STI region 422. There is a distance L4 between the side wall 434 and the STI region 424. In an embodiment, L2 and L4 are greater than or equal to 0.2 μm. A drain region 455 may include the second well 420, the HDD region 426. There are silicide layers on top of the source region 440 and drain region 455.

The third well 480 includes a source region 490 that include a P+ region 491 and a P-LDD region 485. The third well 480 further includes a fifth STI region 482 and a sixth STI region 484. In an embodiment, there is also an N+ region 483 between the STI regions 482 and 484.

The separator structure 450 includes a separator well 430 that is implanted with an n-type material. The separator well 430 may have a concentration of n-type material in the ranges of 5×10¹⁵ cm⁻³ to 1×10¹⁸ cm⁻³. The separator well includes separator walls 432 and 434. The separator wall 432 separates the first well 410 and the second well 420. The separator wall 434 separates the second well 420 and the third well 480. The wall thickness L1 and L3 are greater than or equal to 0.2 μm. The distances L2 and L4 are greater than or equal to 0.2 μm. The gate length Lg1 and Lg2 are greater than or equal to 0.6 μm. The drain region 455 may include part of the separator well 430.

In an embodiment, the semiconductor structure 400 includes silicide layers 416, 442, 427, 461, 471, 486, and 492. The silicide layer 416 is on top of an N+ region 413 between the STI regions 412 and 414. The silicide layer 442 is on top of the P+ region 441. The silicide layer 427 is on top of the HDD region 426 between the STI regions 422 and 424. The silicide layer 461 is on top of the gate region 460. The silicide layer 471 is on top of the gate region 470. The silicide layer 486 is on top of an N+ region 483 between the STI regions 482 and 484. The silicide layer 492 is on top of the P+ region 491.

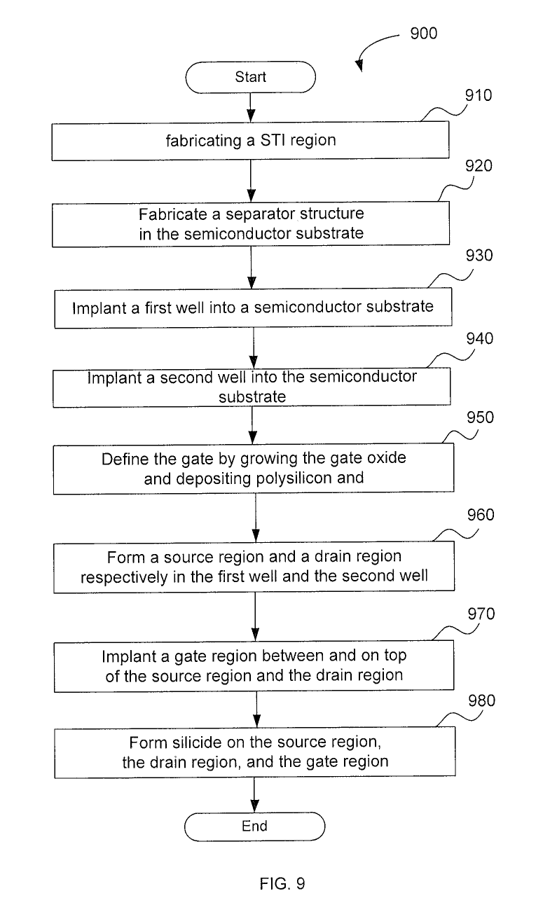

FIG. 9 shows an exemplary fabrication process 900 for fabricating a semiconductor device with increased breakdown voltage. The method 900 is for illustration only, and the processes described below do not have to be carried out in the described order. Also, other fabrication steps including but not limited to initial processing and post processing steps may be introduced.

In the fabrication process 900, an STI region is fabricated by depositing semiconductor regions in the well (910). This may include depositing an etched semiconductor substrate with a dielectric material such as Si0₂, though any suitable material can be used, to form shallow trench isolation regions. The STI region adjacent to a source in the first well and another STI region adjacent to a drain in the second well may provide isolation and protection to the transistor. Depositing an additional STI region in between the gate and the drain may increase the breakdown voltage of the transistor. The fabricated STI region may be partially in the second well and partially in a separator structure.

A separator structure is formed by fabricating a semiconductor substrate in the semiconductor substrate (920). This may include implanting a semiconductor substrate with an appropriate impurity to form a deep N-well. The N-well has a lower concentration of n-type material than the second well. The N-well may include a separator wall that separates the first well and the second well completely. The separator wall may have a uniform thickness.

A first well is fabricated by implanting the first well into a semiconductor substrate (930). This may include implanting a semiconductor substrate with an appropriate impurity to form a P-well or an N-well. For example, implanting the substrate with boron, a p-type material, forms the P-well, while implanting the substrate with phosphorous or arsenic, both n-type materials, forms the N-well.

A second well is fabricated by implanting a semiconductor substrate into the semiconductor substrate (940). This may include implanting a semiconductor substrate with an appropriate impurity to form a P-well or an N-well. The first well and the second wells have different conductivity types. For example, the second well may be an N-well when the first well is a P-well. The second well may be a P-well when the first well is an N-well. The formed first well and second well are separated by the separator structure so that the first well and the second well do not contact each other.

A gate is defined by growing the gate oxide and depositing polysilicon on top of the semiconductor structure (950). This may further include depositing polysilicon on top of the whole semiconductor structure and etching the polysilicon to define a gate region partially above the first well and partially above the second well. This may also include depositing a dielectric material such as SiO₂, though any suitable material can be used, on top of the semiconductor structure to form spacers at each edge of the gate. For example, one spacer may be adjacent to a source region and in contact with the gate while another spacer may be adjacent to a drain region and in contact with the gate.

A source region and a drain region are fabricated by implanting a source semiconductor region and a drain semiconductor region respectively in the first well and the second well (960). This may include implanting a HDD region and an LDD region in the first well to fabricate a source region. This may further include implanting a HDD region in the second well to fabricate a drain region. For example, heavily implanting the substrate with either phosphorous or arsenic, both n-type materials, to create and N+ region forms the source and the drain for an NMOS device. Similarly, heavily implanting the substrate with boron, a p-type material, to create a P+ region forms the source and the drain for a PMOS device.

A gate structure is fabricated by implanting a semiconductor substrate disposed between and on top of the source region and the drain region (970). This may include implanting a semiconductor substrate with polycrystalline silicon, though any suitable material can be used, on top of a gate oxide to form the gate structure. The gate may be heavily doped to avoid the poly depletion, which may reduce the gate capacitance. The gate may be lightly doped to improve gate oxide breakdown voltage, which may reduce the drive strength. Thus, the gate needs to be doped with appropriate impunity depending on the application purpose. For example, the gate may be implanted on the order of 10¹⁸ cm⁻³ to 10²⁰ cm⁻³. Lightly implanting the polycrystalline silicon with the appropriate impurity increases the gate oxide breakdown voltage of the transistor. Lightly implanting n-type material into the polycrystalline silicon to form an N-region creates the gate of an NMOS device, while lightly implanting p-type material polycrystalline silicon to form a P-region creates the gate of a PMOS device. In general, the gate is heavily implanted on the order 10²⁰ cm⁻³ to increase the transistor performance.

A plurality of silicide regions are fabricated by implanting silicide regions on the source region, the drain region, and the gate region (980). This may include depositing metal on top of poly silicon and then alloy to create silicide, though any suitable material can be used, on top of the gate, the source, and the drain of a transistor to form the connection between the fabricated transistor and a metallization layer. The metallization layer forms the interconnections between the fabricated transistor and other devices. In an embodiment, the region of the semiconductor substrate in between the gate and the drain lacks silicide. In other words, there is a gap in the silicide layer between the gate and the drain, requiring the removal of any silicide in this region.

The methods, devices, and logic described above may be implemented in many different ways in many different combinations of hardware. For example, all or parts of the devices may be included in a phone, a laptop, a circuitry, a controller, a microprocessor, or an application specific integrated circuit (ASIC), or may be implemented with discrete logic or components, or a combination of other types of analog or digital circuitry, combined on a single integrated circuit or distributed among multiple integrated circuits.

The embodiments disclose are for illustrative purposes only, and are not limiting. Many other embodiments and implementations are possible within the scope of the systems and methods. Accordingly, the devices and methods are not to be restricted except in light of the attached claims and their equivalents.

What is claimed is:

1. A semiconductor device, comprising:
a first well implanted in a semiconductor substrate;
a second well implanted in the semiconductor substrate; and
a separator structure implanted in the semiconductor substrate that separates the first well and the second well so that the first well and the second well do not contact each other.

2. The semiconductor device of claim 1, wherein the separator structure comprises a separator well comprising a side wall that that separates the first well and the second well.

3. The semiconductor device of claim 1, wherein the first well comprises a source region and the second well comprises a drain region; and wherein the semiconductor device further comprises a gate region disposed between the source region and the drain region.

4. The semiconductor device of claim 2,
wherein the first well is implanted with a material having a first conductivity type; and
wherein the second well and the separator well are implanted with a material having a second conductivity type.

5. The semiconductor device of claim 4, wherein the first conductivity type is p-type and the second conductivity type is n-type.

6. The semiconductor device of claim 4, wherein the separator structure has a greater depth than the first well and the second well.

7. The semiconductor device of claim 4, wherein the separator structure comprises a deep N-well having a lower concentration of n-type material than the second well.

8. The semiconductor device of claim 4, wherein the side wall has a thickness greater than or equal to 0.2 μm.

9. A semiconductor device, comprising:
a first well implanted into a semiconductor substrate and comprising a source region;
a second well above the semiconductor substrate and comprising a drain region;
a gate region disposed between the source region and the drain region and having a gate length; and
a separator wall that separates the first well and the second well, the separator wall having a wall thickness,
wherein a distance between the first well and the second well is greater than or equal to the wall thickness and less than the gate length.

10. The semiconductor device of claim 9, further comprising a deep N-well having a greater depth than the first well and the second well, the deep N-well comprising the separator wall.

11. The semiconductor device of claim 9, wherein the second well comprises a shallow trench isolation (STI) region and a distance between the first well and the STI region is greater than or equal to 0.4 μm.

12. The semiconductor device of claim 10, wherein the deep N-well has a lower concentration of n-type material than the second well.

13. The semiconductor device of claim 10, wherein the gate length is greater than or equal to 0.6 μm.

14. The semiconductor device of claim 10, wherein the wall thickness is greater than or equal to 0.2 μm.

15. The semiconductor device of claim 12, wherein the first well comprises two separate STI regions.

16. The semiconductor device of claim 12, wherein a STI region is disposed partially in the second well and partially in the deep N-well.

17. A method for fabricating a semiconductor device, comprising:
implanting a first well into a semiconductor substrate;
implanting a second well into the semiconductor substrate; and
fabricating a separator structure in the semiconductor substrate that separates the first well and the second well so that the first well and the second well do not contact each other.

18. The method of claim 17, further comprising:
implanting a source region and a drain region respectively in the first well and the second well;
implanting a gate region disposed between the source region and the drain region; and
implanting silicide regions on the source region, the drain region, and the gate region.

19. The method of claim 17, wherein fabricating a separator structure in the semiconductor substrate comprises:
implanting a deep N-well having a lower concentration of n-type material than the second well.

20. The method of claim 17, further comprising: fabricating a STI region that is partially in the second well and partially in the separator structure.
